(19) United States
(12) Patent Application Publication
(10) Pub. No.: US 2026/0372108 A1
(43) Pub. Date: Nov. 19, 2026

(54) POWER MODULE FOR SUPPLYING POWER TO AN ELECTRICAL LOAD OF AN AIRCRAFT, POWER SUPPLY

(71) Applicant: SAFRAN ELECTRICAL & POWER, BLAGNAC (FR)

(72) Inventor: Stéphane GUENOT, MOISSY-CRAMAYEL (FR)

(21) Appl. No.: 19/133,456

(22) PCT Filed: Nov. 28, 2023
(86) PCT No.: PCT/EP2023/083334

§ 371 Date: May 28, 2025

(30) Foreign Application Priority Data
Dec. 7, 2022 (FR) FR2212868

(51) Int. Cl. H10W 42/60; H10W 74/10; H10W 90/00; H10W 90/10

(52) U.S. Cl. CPC H10W 42/60; H10W 74/114; H10W 90/753; H10W 90/10

(57) ABSTRACT

A power module for supplying power to an electrical load of an aircraft. The power module including a plurality of power electronic components mounted on a support substrate, at least one encapsulation layer for encapsulating the plurality of power electronic components in order to protect them, at least one power electrical connection connected to at least one power electronic component, at least one fusible protection layer in which at least one portion of the power electrical connection extends, the fusible protection layer being configured to change state when a current greater than an allowable threshold flows in the portion of the power electrical connection so as to permanently stop the flow of current in the portion.

### TECHNICAL FIELD

The present invention relates to the field of protection against electric arcs in a power supply system for at least one electrical load on an aircraft.

It is well known that climate change is a major concern for many legislative and regulatory bodies throughout the world. Various restrictions on carbon emissions have been, are being or will be adopted by different countries. In particular, an ambitious standard applies both to new types of aircrafts and to those already in circulation, requiring the implementation of technological solutions so as to bring them into line with current regulations. For several years now, the civil aviation has been working to help combat climate change.

The technological research efforts have already led to significant improvements in the environmental performance of the aircrafts. The Applicant takes into account the impacting factors in all the design and development phases to obtain aeronautical elements and products that consume less energy, are more environmentally friendly and whose integration and use in civil aviation have moderate environmental consequences with the aim of improving the energy efficiency of the aircrafts.

This ongoing research and development work focuses in particular on new generations of hybrid thermal and electric aircraft engines. The objective of the Applicant is to develop aircrafts incorporating a high-power electrical generation system. This would allow to increase the proportion of electrical equipment on board to reduce fuel consumption.

In practice, with reference to FIG. 1, a simplified power supply system according to the prior art is shown for supplying power to an electrical load L from a power source S via a power device DP. In practice, the power source S may be an electrical battery, a fuel cell or an electric machine capable of operating as a motor and generator to draw mechanical energy from a shaft of the aircraft turbomachine to produce electrical energy. In practice, a power supply system comprises a plurality of power sources S and a plurality of electrical loads L.

In a known way, with reference to FIG. 1, a power device DP comprises one or more power modules M1 for converting electrical energy, e.g. inverters. A power module M1 comprises a number of electronic components controlled to perform the conversion function. Their number depends on the amount of energy that the power module M1 has to convert. In practice, the power device DP is configured to receive a control setpoint PCONS. for example switching orders of switches, which is transmitted to each power module M1 in order to parameterize the conversion of electrical energy as required.

With reference to FIG. 2, a power module M1 typically comprises a substrate 11 on which power electronic components 12, in particular electronic chips, are mounted. In this example, the power electronic components 12, whether controlled or not, are connected by electrical connections 14 to allow an electrical connection. The power electronic components 12 are protected by an encapsulation layer 15, which provides electrical insulation, and a protective cover 17. The power module M1 comprises at least one power connector 13P configured to interface with a power source S or an electrical load L. The power module M1 also comprises at least one data connector 13D, to allow the control of the so-called controllable power electronic components 12. By controllable component we mean a component whose state may be modified under the effect of a command such as an electrical signal sent to the latter. The power transistors are one of the components that may be controlled. The nature of the signals conveyed by the data connector 13D may vary depending on the nature of the electrical commands and information exchanged with the control setpoint PCONS. The structure of such a power module M1 is known to the person skilled in the art.

In practice, various faults may appear at any point in the power supply system: a short-circuit occurring in an equipment or a wiring, a damage to a component subjected to unforeseen stress, an inoperative component, an electric arc, etc. In order to protect the various items of equipment against excessively high currents, controllable protection members OPC are known to isolate a part of the items of equipment and thus protect them. The controllable protection members OPC generally take the form of electromechanical contactors or so-called static components, using semiconductor components. A controllable protection member OPC is used to isolate the fault, for example a power source S as shown in FIG. 1. In a known way, in the event of detection of a fault in a power source S, the controllable protection members OPC are controlled so as to reconfigure the power supply system in order to supply the electrical loads L with the power sources S available.

To reset a controllable protection member OPC, it is often necessary to provide another protection component with a dissimilar breaking technology, for example, a fuse technology.

With reference to FIG. 1, a fuse-type protection member OPF allows an electrical connection to be permanently disconnected. In a known way, such a protection member of the OPF fuse type, for example made of silica, may change state in order to absorb an electric arc and cut off the flow of current on the electrical line on which it is mounted. Under the effect of a strong current, the silica will vitrify to cut off the flow of current. Advantageously, a protection member of the OPF fuse type may absorb a large quantity of electrical energy to ensure that the electric arc is extinguished without causing material to be projected or other damage.

In practice, because it is positioned in series with the equipment to be protected, for example a power source S as shown in FIG. 1, the protection member of the OPF fuse type must be sized to withstand the main current and the transients on the supply line connecting the power source S to the power device DP. In the event of a short-circuit and a fault in the controllable protection member OPC, the protection member of the OPF fuse-type will cut-off at a high value cut-off current. In practice, as the current increases up to the cut-off current, the currents flowing in the power module M1 also increase and are likely to damage the power electronic components 12 of the power modules M1. In other words, when the fuse-type protection members OPF cut off the current flow, the power electronic components 12 of the power modules M1 are likely to have already been damaged, which presents a significant disadvantage. This makes the return to service expensive. In addition, the fuse-type protection members OPF are bulky, dissipative and cooled by natural air convection. To reduce the risk of overheating, a fuse-type protection member OPF is generally oversized. This has a major impact on the power supply system, which has to remain compact.

An immediate solution to eliminate this disadvantage would be to provide fuse protection members OPF with a lower cut-off current, but this would lead to untimely cut-off in the event of a current fluctuation on the power supply line between the power source S and the power device DP.

The invention thus aims to eliminate at least some of these disadvantages by proposing a fusible protection member for protecting the power electronic components of a power module which may be faulty, without increasing complexity and overall dimension.

The patent US20070085181A1 is a known application for a power module comprising semiconductors and a protection device to prevent a destruction by explosion of the power module following the flow of excessively high currents.

### PRESENTATION OF THE INVENTION

The invention relates to a power module for supplying power to at least one electrical load of an aircraft, the power module comprising a plurality of power electronic components mounted on a support substrate, at least one encapsulation layer for encapsulating the plurality of power electronic components in order to protect them, at least one power electrical connection connected to at least one power electronic component.

The invention is remarkable in that the power module comprises at least one fusible protection layer wherein at least one portion of the power electrical connection extends, the fusible protection layer being configured to change state when a current, greater than an acceptable threshold, flows in the portion of the power electrical connection so as to permanently stop the flow of current in said section.

Thanks to the invention, a fuse protection is integrated directly into the power module. It is used to permanently stop the flow of current in a portion of a power electrical connection. In addition, this fuse protection allows the power electronic components to be held in an encapsulation layer to protect them. The fusible protection layer absorbs the energy released by an electric arc and stops it circulating. In this way, an electric arc is contained locally, protecting the power electronic components. Having a fuse protection integrated into the power module is a major advantage, as it eliminates the need for a dedicated fuse-type protection member, which is bulky and complex to install.

According to one aspect, several electrical connections comprise a portion in the fusible protection layer. This allows to permanently stop the flow of current in said portions for said electrical connections. In a preferred aspect, all electrical connections comprise a portion in the fusible protection layer.

Preferably, the fusible protection layer covers several elements of the power module, in particular the semiconductors (the chips), potentially all the electrical connections, the passive components or any other component placed in the power module and likely to release energy in the event of a fault.

According to one aspect, the power electrical connection is connected between two power electronic components.

According to one aspect, the power electrical connection is connected between at least one power electronic component and at least one electrical power connector comprising at least one portion extending outside the encapsulation layer.

According to one aspect, the power electrical connection is partly in the encapsulation layer and partly in the fusible protection layer.

According to one aspect, the power module comprises at least one offset connector connecting the power electronic component to the power electrical connection, the power electrical connection extending only into the fusible protection layer. The fusible protection layer absorbs all the heat associated with the fault. The power electronic components remain protected in the encapsulation layer.

Preferably, the offset connector is positioned on the support substrate.

Preferably, the power module comprises at least one printed circuit board mounted at the interface between the encapsulation layer and the fusible protection layer, the offset connector being connected to the power electrical connection via the printed circuit board. The printed circuit board comprises the electrical power connections and may be conveniently replaced.

In one aspect, the power module comprises at least one data electrical connection connected to a data connector, the data electrical connection comprising at least one portion extending into the fusible protection layer. Advantageously, the power electronic components are fully protected.

The invention also relates to a power supply system for supplying at least one aircraft electrical load comprising at least one power device comprising at least one power module as previously presented.

The invention also relates to a method for manufacturing a power module for supplying power to at least one electrical load of an aircraft, the power module comprising a plurality of power electronic components mounted on a support substrate, the method comprising steps consisting in:
Connecting at least one power electrical connection to a power electronic component,
Depositing an encapsulation layer on the power electronic component so as to protect it, and
Depositing a fusible protection layer on at least one portion of the power electrical connection, the fusible protection layer being configured to change state when a current, greater than an acceptable threshold, flows in the portion of the power electrical connection so as to permanently stop the flow of current in said portion.

Preferably, the fusible protection layer is deposited on the encapsulation layer.

In one aspect, the fusible protection layer is deposited directly on the encapsulation layer, which facilitates assembly.

According to one aspect, the fusible protection layer is deposited indirectly on the encapsulation layer, for example by using an intermediate support. The intermediate support acts as an interface to contain the fusible protection layer. This allows to choose materials for the fusible protection layer that would be incompatible with the encapsulation layer. In one aspect, the intermediate support is a printed circuit board and electrical connections are specifically made on the printed circuit board to provide the fuse function.

### PRESENTATION OF FIGURES

The invention will be better understood on reading the following description, given by way of example, with reference to the following figures, given by way of non-limiting examples, wherein identical references are given to similar objects.

FIG. 1 is a schematic representation of a power supply system according to the prior art.

FIG. 2 is a schematic representation of a power module according to the prior art.

FIG. 3 is a schematic representation of a power supply system according to the invention.

FIG. 4 is a simplified schematic representation of a power supply system according to the invention.

FIG. 5 is a schematic representation of a power module according to one embodiment of the invention.

FIG. 6 is a close-up schematic representation of an electrical connection of FIG. 5 comprising a portion mounted in the fusible protection layer.

FIG. 7 is a close-up schematic representation of the electrical connection of FIG. 5 after an electric arc has been absorbed by the fusible protection layer.

FIG. 8 is a schematic representation of a power module according to another embodiment of the invention.

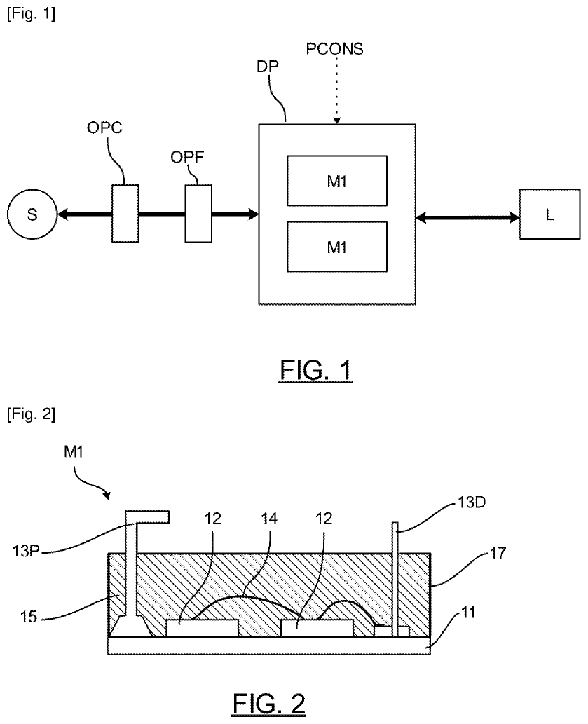

It should be noted that the figures set out the invention in detail in order to implement the invention, said figures of course being able to be used to better define the invention if necessary.

### DETAILED DESCRIPTION OF THE INVENTION

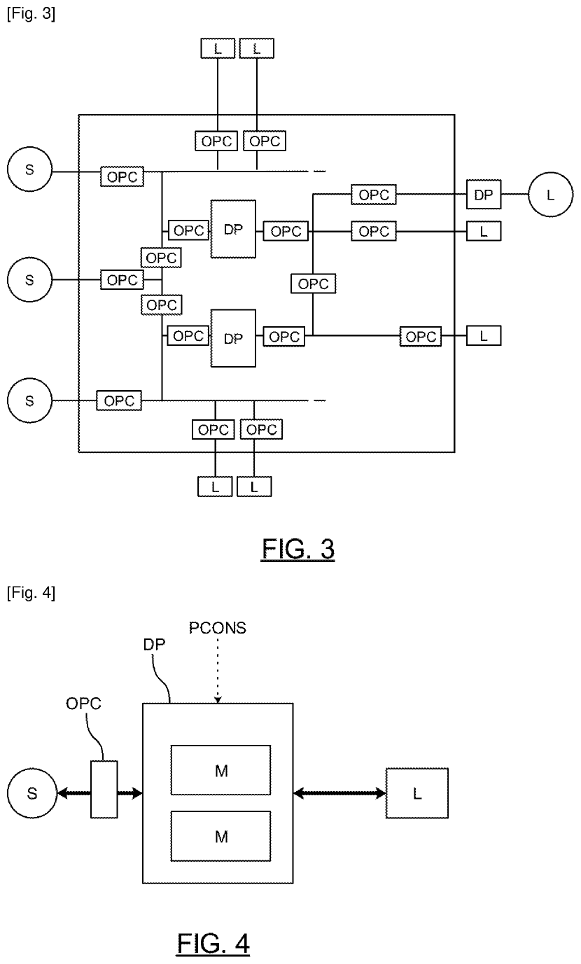

With reference to FIG. 3, a power supply system for supplying power to a plurality of electrical loads L from a plurality of power sources S is shown. A power source S may be, in particular, in the form of an electrical battery, a fuel cell or an electric machine configured to operate as a motor or as a generator for drawing mechanical energy from a shaft of an aircraft turbomachine. The electrical load L may take the form of an actuator or a motor, in particular comprising two stator stars to improve the redundancy.

Still with reference to FIG. 3, the power supply system comprises a plurality of power devices DP for converting and processing the electrical energy from the power sources S to supply power to the electrical loads L. By way of example, a power device DP may comprise several power modules for supply power to the various stator stars of an electrical machine.

Still with reference to FIG. 3, the power supply system comprises a plurality of controllable protection members OPC, for example contactors, so as to allow to isolate an equipment fault and allow the power supply system to be reconfigured for a degraded operation.

In a simplified manner, with reference to FIG. 4, a system for supplying a single electrical load L from a single power source S is shown for the sake of clarity and brevity. In FIG. 4, the power supply system comprises a power device DP for converting and processing the electrical energy from the power source S to power supply the electrical load L. A controllable protection member OPC is provided on the power supply line connecting the power source S to the power device DP.

As illustrated in FIG. 4, the power device DP comprises a plurality of power modules M. Preferably, each power module M is configured to perform at least one conversion function, for example, to process a three-phase current for an inverter of an electrical machine or to supply a distribution current to an electrical load L.

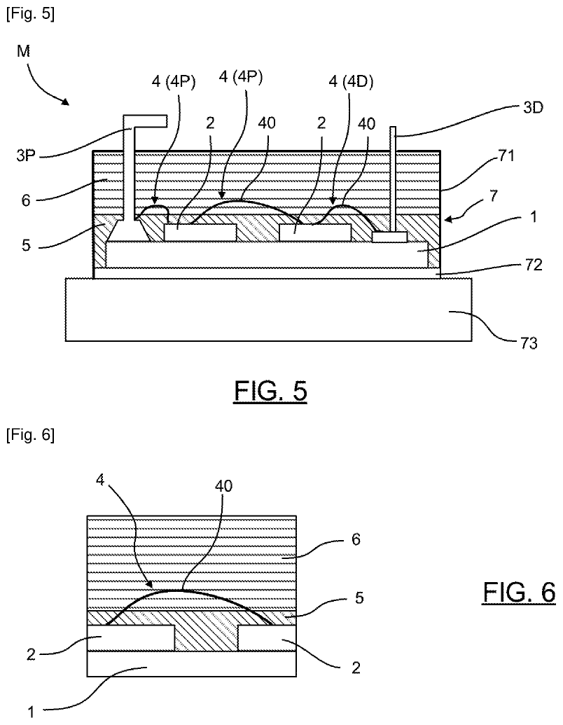

With reference to FIG. 5, a power module M according to a first embodiment of the invention is shown. The power module M comprises a plurality of power electronic components 2 mounted on a support substrate 1. In this example, the power electronic components 2 are in the form of electronic chips or semiconductors.

The power module M comprises at least one power connector 3P configured to receive power. It is configured, for example, to be connected to an electrical load L or a power source S. The power connector 3P is accessible from outside the power module M.

The power module M comprises at least one data connector 3D configured to receive a control setpoint PCONS (FIG. 4), for example, switch or transistor switching orders. For example, it is configured to be connected to a control calculator (not shown). The data connector 3D is accessible from outside the power module M.

In this example, the power electronic components 2 and the connectors 3P, 3D are connected by electrical connections 4, in particular wire bonding, but it goes without saying that other types of connection may be suitable. With reference to FIG. 5, among the electrical connections 4, a distinction is made between, on the one hand, electrical power connections 4P which allow high currents, for example greater than 10 A, to flow and, on the other hand, electrical data connections 4D which allow low currents, for example less than 10 A, to flow.

The power module 4 comprises an encapsulation layer 5, covering the plurality of power electronic components 2 in order to protect them. Preferably, the encapsulation layer 5 is made of a silicone-based dielectric gel, a thermosetting two-component dielectric silicone gel or a Parylene insulating layer. Such an encapsulation layer 5 is known to the person skilled in the art. Advantageously, this encapsulation layer 5 provides the electrical insulation. The connectors 3P, 3D comprise at least one portion extending outside the encapsulation layer 5.

The invention is remarkable in that the power module M comprises at least one fusible protection layer 6 into which at least a portion 40 of an electrical connection 4 extends. In this example, several electrical connections 4 comprise a portion 40 in the fusible protection layer 6, in particular, a power electrical connection 4P connecting a power electronic component 2 to a power connector 3P, a power electrical connection 4P connecting the two electronic power components 2 and a data electrical connection 4D connected to the data connector 3D.

The fusible protection layer 6 is configured to change state when a current greater than a permissible threshold flows, so as to permanently stop the flow of current in the electrical connection portions 40 4 located in the fusible protection layer 6.

As illustrated in FIG. 6 schematically representing a power electrical connection 4, a portion 40 is located in the fusible protection layer 6. When a fault occurs inside or outside the power module DP, a current already present in the portion 40 of the electrical connection 4 will increase until it exceeds a permissible threshold, preferably at least equal to twice the nominal current flowing through the portion 40 of the electrical connection 4 in a nominal operating mode. In a few microseconds, the portion 40 of the electrical connection 4 will melt, form a liquid bridge and eventually separate, giving rise to an electric arc.

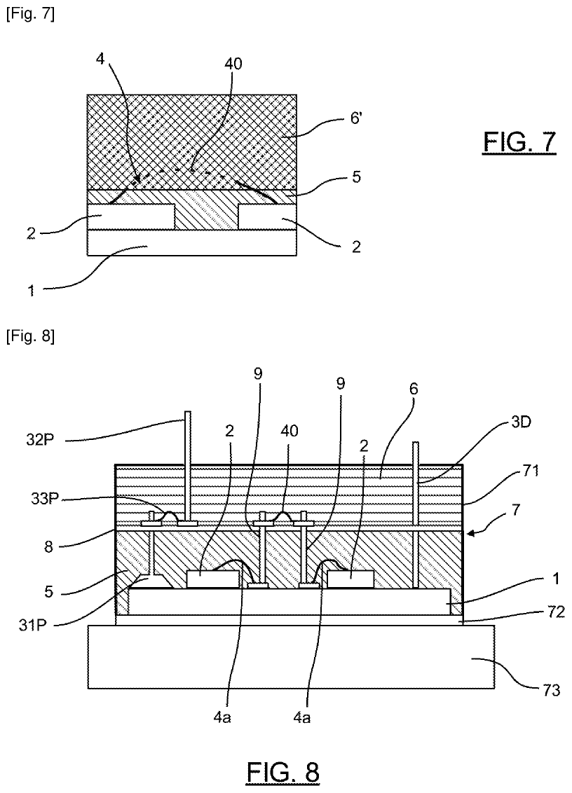

When the permissible threshold is exceeded, the current flowing in the portion 40 of the electrical connection 4 causes a change of state in the fusible protection layer 6, which becomes a cut-off layer 6′, as illustrated in FIG. 7, permanently stopping the flow in said portion 40. Excessive currents may no longer flow, protecting the integrity of the power electronic components 2.

This change of state allows to absorb the energy released by the electrical connection 4. When the fusible protection layer 6 returns to its original state (solid state), it is transformed into a cut-off layer 6′ which ensures the definitive interruption of the current flow in the portion 40 of the electrical connection 4.

The power device DP wherein the faulty power module M is used is then in a safe state, due to the stopping of the fault and the ability of the fusible protection layer 6 (cut-off layer 6′.) to contain the voltage at the electrical connection 4.

The fusible protection layer 6 is preferably configured to change phase during its change of state, under the effect of the presence of a high heat density. Preferably, the fusible protection layer 6 is thermally and chemically stable and compatible with the encapsulation layer 5. Preferably, the fusible protection layer 6 is configured to provide an electrical insulation so as to prevent the propagation of electrical currents from the power electronic components 2, even when the fusible protection layer 6 becomes a cut-off layer 6′. Preferably, the fusible protection layer 6 is hydrophobic and also allows it to withstand fire without releasing toxic fumes. Preferably, the fusible protection layer 6 comprises sand, preferably pure silica sand.

In this example, the fusible protection layer 6 is in direct contact with the encapsulation layer 5.

With reference to FIG. 5, to ensure mechanical protection, the power module is mounted in a case 7 which preferably comprises a soleplate 72 connected to the substrate 1 and a cover 71. Preferably, the connectors 3P, 3D project from the cover 71. In this example, the power module M comprises a dissipator 73 for improving the drainage of calories, which is connected to the soleplate 72, in particular via a thermal interface layer. According to one aspect of the invention, the encapsulation layer 15 and the case 71 are made from a single element.

An example of a method for manufacturing a power module M will now be presented. The power electronic components 2 are positioned on the substrate 1, preferably of the SnAg type. Preferably, the substrate 1 has been previously screen printed to form a redistribution layer for the electrical connectors and the power electronic components 2 are connected to the substrate 1 by reflow.

In this example, the method comprises the steps consisting in:
Connecting at least one electrical connection 4 to a power electronic component 2.
Depositing an encapsulation layer 5 to the power electronic component 2 to protect it,
Stabilizing the encapsulation layer 5, for example by a steaming, polymerization or other operation, and
Depositing a fusible protection layer 6 to at least a portion 40 of the power electrical connection 4.

According to one aspect, the method comprises a step consisting in mounting part of the case 7 before the step consisting in depositing the encapsulation layer 5. This allows the volume of the first part of the case to be used to facilitate the deposition of the encapsulation layer 5. Preferably, the method comprises a step consisting in mounting a second part of the case 7 after the step consisting in depositing the fusible protection layer 6.

Preferably, the encapsulation layer 5 is deposited before the fusible protection layer 6 in order to produce the power module M by deposition of superimposed layers, which is practical.

An example of implementation will be presented with reference to FIGS. 5 to 7. As shown in FIG. 5, the power module M is powered by the power connector 3P which supplies power to two power electronic components 2 via electrical power connections 4P. In this example, a power electronic component 2 is also connected to a data connector 3D via a data electrical connection 4D.

When a short-circuit occurs in the power supply system, the current increases rapidly, particularly in the power connections 4P as shown in FIG. 6.

Advantageously, the portion 40 of the power electrical connection 4 allows to change the state of the fusible protection layer 6, which is transformed into a cut-off layer 6′. In this state, the current flowing in the portion 40 of the power electrical connection 4 is permanently stopped as shown in FIG. 7, which advantageously protects the power electronic components 2 against high value currents. Advantageously, the fusible protection layer 6 absorbs the energy of electrical art to protect the power electronic components 2.

Preferably, when the fusible protection layer 6 changes state, the current is stopped in all the portions 40, i.e. even in those which have not circulated a current greater than the permissible threshold. This is particularly the case for the control electrical connection 4D, wherein there is no high current flow.

The power electronic components 2 are thus protected. All an operator has to do is replace the fusible protection layer 6 and the electrical connections 4P, 4D to put the power module M back into service, which is advantageous.

Another embodiment is shown in FIG. 8. For the sake of clarity and brevity, only the differences with the first design in FIG. 5 will be described. The common or similar elements have the same references in FIG. 8 and will not be described again.

With reference to FIG. 8, the power module M comprises a printed circuit board 8 called “PCB” arranged between the encapsulation layer 5 and the fusible protection layer 6. Advantageously, this allow the electrical connections to be returned to service by creating a boundary between the encapsulation layer 5 and the fusible protection layer 6. This also allows considerable freedom in the choice of materials for the encapsulation layer 5 and the fusible protection layer 6, since they are not in direct contact. This also makes the return to service easier.

In this example, the power module M comprises several offset members 9, housed in the encapsulation layer 5, which are connected on the one hand to a power electronic component 2 and on the other hand to the printed circuit board 8. The power electrical connection 4 is connected only to the printed circuit board 8 and extends into the fusible protection layer 6, and in particular only into the latter.

Thus, following the occurrence of an electric arc, the electrical power connections 4 may be conveniently removed together with the fusible protection layer 6. When returning to service, simply recreate the electrical power connections 4 and depositing a new fusible protection layer 6. The encapsulation layer 5, the power electronic components 2 and the offset members 9 are advantageously unaffected. Preferably, the electrical power connections 4 are pre-wired on the printed circuit board 8, which facilitates installation and return to service.

Preferably, each offset member 9 is in the form of a vertical pillar mounted on the substrate 1. Preferably, each offset member 9 is connected to a power electronic component 2 via an internal electrical connection 4a which preferably extends only into the encapsulation layer 5 as shown in FIG. 8.

In this example, with reference to FIG. 8, the power connector 3P comprises:
an internal part 31P, housed in the encapsulation layer 5, which is mounted on the substrate 1 and connected to the printed circuit board 8,
an external part 32P, partly housed in the fusible protection layer 6 and
an external connection 33P electrically connecting the external part 32P to the internal part 31P via the printed circuit board 8.

Similarly, the external connection 33P extends only into the fusible protection layer 6. The fusible protection layer 6 is configured to change state when a current, greater than a permissible threshold, flows in the external connection 33P so as to permanently stop the flow of current in the external connection 33P. Advantageously, the fusible protection layer 6 may change state when an electric arc occurs in the power connector 3P.

An example of implementation of a method for manufacturing a power module M will now be presented. The power electronic components 2 are positioned on the substrate 1. Preferably, the substrate 1 has been screen-printed to form a redistribution layer for the electrical connectors and the power electronic components 2 are attached to the substrate 1 by reflow with the offset members 9 and the internal electrical connections 4a. Preferably, the internal part 31P of the power connector 3P is also positioned on the substrate 1.

The method comprises a step consisting in depositing an encapsulation layer on the elements positioned on the substrate 1 in order to protect them and form a first assembly.

Next, the method comprises a step consisting in assembling the printed circuit board 8 to the first assembly. The electrical connections 4, the external connection 33P and the external part 32P of the power connector 3P are preferably pre-wired. The assembly may be carried out by brazing or, preferably, by a press-fit operation. Compatible offset members 9 are selected for press mounting. After assembly, the method comprises a step consisting in depositing the fusible protection layer 6. Such a manufacturing method offers a great flexibility in the choice of material for the encapsulation layer 5 and the fusible protection layer 6, since they are not in direct contact.

Thanks to the invention, the current is cut locally in a power module M for lower cut-off currents than in the prior art. This allows to protect the power electronic components 2 and makes the return to service easier. The power of an electric arc is absorbed locally by the fusible protection layer 6. This allows to limit the material projections and the spread of damage.

1. A power module for supplying power to at least one electrical load of an aircraft, the power module comprising:
a plurality of power electronic components mounted on a support substrate,
at least one encapsulation layer for encapsulating the plurality of power electronic components in order to protect the plurality of power electronic components,
at least one power electrical connection connected to at least one of the power electronic components, and
at least one fusible protection layer, several power electrical connections comprise at least one portion in the fusible protection layer, the fusible protection layer being configured to change state when a current, greater than an acceptable threshold, flows in the portion of the power electrical connection so as to permanently stop the flow of current in said portion.

2. The power module according to claim 1, wherein the power electrical connection is connected between two of the power electronic components.

3. The power module according to claim 1, wherein the power electrical connection is connected between the at least one power electronic component and the at least one electrical power connector comprising at least one portion extending outside the encapsulation layer.

4. The power module according to claim 1, further comprising at least one offset connector connecting the power electronic component to the power electrical connection, the power electrical connection extending only into the fusible protection layer.

5. The power module according to claim 4, further comprising at least one printed circuit board mounted at an interface between the encapsulation layer and the fusible protection layer, the offset connector being connected to the power electrical connection via the printed circuit board.

6. The power module according to claim 1, further comprising at least one data electrical connection connected to a data connector, the data electrical connection comprising the at least one portion extending into the fusible protection layer.

7. The power module according to claim 1, wherein the power electrical connection is longitudinal wire comprising several parts with different cross-sections.

8. A power supply system for supplying an aircraft electrical network comprising at least one power device comprising at least one of the power modules according to claim 1.

9. A method for manufacturing a power module for supplying power to at least one electrical load of an aircraft, the power module comprising a plurality of power electronic components mounted on a support substrate, the method comprising:
connecting at least one power electrical connection to one of the power electronic components,
depositing an encapsulation layer on the power electronic component so as to protect the power electronic component, and
depositing a fusible protection layer on at least one portion of the power electrical connection, the fusible protection layer being configured to change state when a current, greater than an acceptable threshold, flows in the portion of the power electrical connection so as to permanently stop the flow of current in said portion.
